(19) United States
(12) Patent Application Publication
(10) Pub. No.: US 2014/0224427 A1
(43) Pub. Date: Aug. 14, 2014

(54) DRY ETCHING APPARATUS AND CLAMP THEREFOR

(71) Applicant: FUJIFILM CORPORATION, Tokyo (JP)

(72) Inventor: Shuji TAKAHASHI, Ashigarakami-gun (JP)

(73) Assignee: FUJIFILM CORPORATION, Tokyo (JP)

(21) Appl. No.: 14/181,279

(22) Filed: Feb. 14, 2014

(30) Foreign Application Priority Data
Feb. 14, 2013 (JP) 2013-026323

(51) Int. Cl. H01L 21/687; H01J 37/20

(52) U.S. Cl. CPC H01L 21/687; H01J 37/20
USPC 156/345.51

(57) ABSTRACT

A dry etching apparatus according to an aspect of the present invention is provided with a stage on which a substrate including a resist mask on an outermost layer thereof is mounted; a clamp for holding down the substrate from above the resist mask to fix the substrate on the stage; a chamber within which the stage and the clamp are housed; an exhaust device which evacuates the chamber; a process gas supply device which supplies a process gas into the chamber; and a power supply for supplying electrical power used to generate plasma within the chamber, wherein the clamp has an annular structure for covering an entire outer circumference and side surface of the substrate, and an antiadhesion layer composed of an inorganic film for preventing an adhesion of a resist material is formed on the contact surface side of the clamp in contact with the substrate.

### BACKGROUND OF THE INVENTION

1. Field of the Invention

The present invention relates to a dry etching apparatus and a clamp for the dry etching apparatus, and particularly, to the structure of the clamp for fixing a substrate on a stage inside a chamber and a dry etching apparatus using the clamp.

2. Description of the Related Art

As a device which fixes a substrate (for example, a silicon wafer) on a stage in a dry etching apparatus used to manufacture semiconductor devices, MEMS (Micro-Electro-Mechanical System) devices, and the like, a configuration in which the peripheral part of the substrate is press-fixed with a clamp is known (see Japanese Patent Application Laid-Open No. 2002-299422). The invention described in Japanese Patent Application Laid-Open No. 2002-299422 proposes a wafer-fixing clamp for preventing adhesion between the wafer and a part of the clamp pressed on the wafer caused when the wafer press-fixed with the clamp is detached therefrom after an etching treatment, and the degradation of product yields.

The clamp described in Japanese Patent Application Laid-Open No. 2002-299422 includes a plurality of contactors to be pressed against a wafer, a contactor support in which these contactors are circularly disposed, and a support transfer device which moves the contactor support close to or away from the wafer, and is configured so that each contactor includes a contacting portion having one of point, line and surface contacts with the wafer and the contacting portion is pressed against an edge near the outer circumference of the wafer from a direction substantially perpendicular to a wafer surface.

### SUMMARY OF THE INVENTION

In a dry etching process, a mask (resist mask) formed using a resist material is used in order to perform patterning on a material to be etched. Since deep etching is performed and a hard material is processed when, for example, a MEMS device is fabricated, the film of a resist used for the mask is thick in many cases. In a dry etching apparatus configured in the manner that a substrate is held down with a clamp from above the resist mask to fix the substrate on a stage, the substrate is heated during etching, and the clamp is pressed against the resist mask. Accordingly, the dry etching apparatus has the problem that a resist on the substrate adheres (sticks) to the clamp.

The clamp shown in Japanese Patent Application Laid-Open No. 2002-299422 has a structure in which a plurality of contactors (eight claw members in FIG. 2 of Japanese Patent Application Laid-Open No. 2002-299422) to have contact with the wafer are arranged in an annular support (circular frame). The clamp is thus configured to partially hold down the outer circumference of the wafer with the plurality of contactors. Accordingly, plasma infiltrates from a gap in an unpressed part, and therefore, the outer-circumferential uncovered part and side surface of the substrate are etched. This can be a cause for damage to the substrate, such as the delamination of the resist film, and the generation of particles.

In addition, abnormal electrical discharge may occur in the gap between the clamp and the stage. Thus, the clamp has the problem that, for example, particles are generated or a device being etched becomes defective due to the abnormal electrical discharge.

Yet additionally, the conventional clamp uses resin (for example, polytetrafluoroethylene (PTFE), polyimide (PI), polyether ether ketone (PEEK), or polyphenylene sulfide (PPS)) for a portion of the clamp to have contact with the substrate. Since oxygen plasma is used in a post-etching plasma cleaning process in the dry etching apparatus, a resin material low in resistance to oxygen plasma is easily etched. Consequently, the period of apparatus maintenance is shortened and an apparatus operating rate becomes lower.

The present invention has been accomplished in view of such circumstances as described above. It is therefore an object of the present invention to provide a dry etching apparatus and a clamp for the dry etching apparatus which solve the above-described problems and can prevent a resist mask from adhering to the clamp and the outer peripheral part and side surface of a substrate from being abraded due to etching.

In order to achieve the above-described object, the following aspects of the invention are provided:

(First aspect): A dry etching apparatus according to a first aspect is provided with a stage on which a substrate including a resist mask on an outermost layer thereof is mounted; a clamp for holding down the substrate from above the resist mask to fix the substrate on the stage; a chamber within which the stage and the clamp are housed; an exhaust device which evacuates the chamber; a process gas supply device which supplies a process gas into the chamber; and a power supply for supplying electrical power used to generate plasma within the chamber, wherein the clamp has an annular structure for covering an entire outer circumference and a side surface of the substrate, and an antiadhesion layer composed of an inorganic film for preventing an adhesion of a resist material is formed on a contact surface side of the clamp in contact with the substrate.

According to the dry etching apparatus of the first aspect, the resist mask is provided on the outermost layer of the substrate placed on the stage, and the clamp holds down the substrate from above this resist mask to fix the substrate. The antiadhesion layer composed of the inorganic film is provided on the surface of the clamp in contact with the substrate (i.e., the surface of the clamp in contact with the resist mask). Consequently, the resist material is prevented by this antiadhesion layer from adhering to the clamp.

The inorganic film is superior in resistance to plasma (resistance to oxygen plasma in particular) to an organic film. In addition, the clamp of the present aspect has an annular (closed loop-shaped) structure for covering the entire outer circumference and side surface of the substrate. Consequently, the outer circumference and side surface of the substrate are protected by the clamp. As described above, the dry etching apparatus adopts the clamp having a structure in which the entire circumference of the substrate is covered and plasma is less likely to flow into the outer circumference and side surface of the substrate. Consequently, it is possible to prevent the outer circumference and side surface of the substrate from being abraded due to etching.

(Second aspect): In the dry etching apparatus according to the first aspect, a degree of planarity of a surface of the antiadhesion layer is preferably 10 μm or lower in terms of a value of Ra.

The resist material is less likely to adhere to the surface of the antiadhesion layer with an increase in planarity. If the value of Ra (center-line average roughness) is used as an index representative of planarity, Ra of the antiadhesion layer is desirably 10 μm (micrometers) or smaller. In addition, since the antiadhesion effect of the antiadhesion layer is higher in proportion to the lower surface energy thereof, it is preferable to form an antiadhesion layer composed of a low surface energy inorganic material.

(Third aspect): In the dry etching apparatus according to the first or second aspect, the antiadhesion layer can be composed of an inorganic film containing at least one type of material selected from a group consisting of quartz, alumina, sapphire, yttria, zirconia, and tantalum pentoxide.

An insulating material can also be used as the antiadhesion layer. According to an aspect in which an insulating antiadhesion layer is adopted, it is possible to reliably prevent abnormal electrical discharge between the clamp and the stage in combination with a clamp structure for surrounding the entire outer circumference and side surface of the substrate.

(Fourth aspect): In the dry etching apparatus according to the first or second aspect, the antiadhesion layer can be composed of metal nitride.

By using a material not containing oxygen as the antiadhesion layer, it is possible to avoid causing oxygen to be released during an etching treatment, thereby improving a resist selection ratio.

(Fifth aspect): In the dry etching apparatus according to any one of the first to fourth aspects, the antiadhesion layer can be composed of an inorganic film containing a fluorine group.

As described already, the adhesion-blocking function of the antiadhesion layer is more superior with a decrease in the surface energy of the antiadhesion layer. A material containing a fluorine group is low in surface energy and is, therefore, suitable for the antiadhesion layer.

(Sixth aspect): In the dry etching apparatus according to the first or second aspect, the antiadhesion layer can be composed of an electroconductive material.

By adopting a configuration in which the antiadhesion layer is formed using the electroconductive material, it is possible to connect a substrate surface to a ground through the antiadhesion layer. Thus, it is possible to prevent the charge-up of the substrate surface.

(Seventh aspect): In the dry etching apparatus according to the sixth aspect, the antiadhesion layer can be composed of an electroconductive material containing at least one type of material selected from a group consisting of SiC, NiCr, Pt, PtO, Ir, IrO, Ru, and RuO.

The electroconductive materials enumerated in the seventh aspect are high in resistance to plasma, and therefore, suitable as the material of the antiadhesion layer.

(Eighth aspect): In the dry etching apparatus according to any one of the first to seventh aspects, the antiadhesion layer composed of an inorganic film can also be provided on an inner sidewall surface of the clamp surrounding a side surface of the substrate.

It is desirable to adopt a configuration in which the antiadhesion layer is provided not only on the surface of the clamp on the side thereof in contact with the substrate but also on the inner sidewall surface of the clamp surrounding the side surface of the substrate. More preferably, the configuration is such that the antiadhesion layer is provided on the entire rear surface (surface in contact with the substrate) of the clamp facing the substrate and on the entire inner sidewall surface thereof

For reasons of the structure of the clamp, plasma is less likely to flow into the vicinity of the outer circumference and side surface (outer-peripheral end face) of the substrate. With the synergetic effect of such a configuration, it is possible to more effectively prevent abnormal electrical discharge between the side surface (side edges) of the substrate and the clamp, if the antiadhesion layer is composed of an insulating material in the eighth aspect.

In addition, if the antiadhesion layer is composed of an electroconductive material in the eighth aspect, it is easy to connect the substrate surface to the ground through the electroconductive antiadhesion layer.

(Ninth aspect): In the dry etching apparatus according to any one of the first to eighth aspects, the clamp can be configured in the manner that a portion of the clamp in contact with the substrate has a V-shape as the cross-sectional shape of a cutting plane perpendicular to a substrate surface.

According to the ninth aspect, the contact area between the clamp and the substrate (resist mask) becomes smaller, and therefore, the antiadhesion effect becomes even higher.

(Tenth aspect): In the dry etching apparatus according to any one of the first to ninth aspects, the clamp has a structure including a tapered shape, as a cross-sectional shape of a cutting plane perpendicular to a substrate surface, in which a thickness of the clamp decreases from an outer periphery of the substrate toward a center thereof.

According to the tenth aspect, the upper part (front surface side exposed to plasma) of the clamp includes an inclined surface. This configuration makes it easy for a gas to flow outside the substrate along the inclined surface of the clamp shape when a flow of the gas from above the substrate toward the substrate surface is generated within the chamber. Accordingly, the gas flow stabilizes, thus making it possible to improve a flow of the gas in the vicinity of the outer circumference of the substrate (uncovered area near the boundary with the clamp-covered area) not covered with the clamp. Consequently, an improvement is made to etching performance in the uncovered area in the vicinity of the boundary of the outer peripheral part of the substrate with the clamp.

(Eleventh aspect): In the dry etching apparatus according to any one of the first to tenth aspects, the clamp can be configured to have a structure of being integrated with a straightening vane for covering a space between the stage and walls of the chamber, and a plurality of holes for a gas to flow through are provided in the straightening vane.

According to the eleventh aspect, a gas flow within the chamber can be made uniform with respect to the substrate, thereby improving the uniformity of etching.

(Twelfth aspect): A clamp for a dry etching apparatus according to a twelfth aspect is used to hold down a substrate including a resist mask on an outermost layer thereof from above the resist mask and fix the substrate on a stage of the dry etching apparatus. The clamp has an annular structure for covering an entire outer circumference and a side surface of the substrate, and an antiadhesion layer composed of an inorganic film for preventing an adhesion of the resist mask is formed on a surface of the clamp in contact with the substrate.

In the clamp for the dry etching apparatus according to the twelfth aspect, the specific items according to the second to eleventh aspects can be combined as appropriate.

According to the present invention, it is possible to prevent the resist mask from adhering to the clamp. It is also possible to prevent the outer circumference and side surface of the substrate from being abraded due to etching.

### BRIEF DESCRIPTION OF THE DRAWINGS

FIG. 1 is a drawing illustrating a schematic configuration of a dry etching apparatus according to an embodiment of the present invention;

FIG. 2 is a top view of a clamp in the present embodiment;

FIG. 3 is a cross-sectional view of the clamp cut along the 3-3 line of FIG. 2;

FIG. 4 is a cross-sectional view illustrating a configuration example of a portion of the clamp to have contact with a substrate;

FIG. 5 is a cross-sectional view illustrating an example of the cross-sectional shape of another configuration of the clamp;

FIG. 6 is a cross-sectional view illustrating an example of the cross-sectional shape of yet another configuration of the clamp;

FIG. 7 is a plan view illustrating an example of a clamp integrated with a straightening vane; and

FIG. 8 is a drawing illustrating a schematic configuration of a dry etching apparatus to which the clamp illustrated in FIG. 7 is applied.

### DETAILED DESCRIPTION OF THE PREFERRED EMBODIMENTS

Hereinafter, embodiments of the present invention will be described in detail according to the accompanying drawings.

<Overall Configuration of Dry Etching Apparatus>

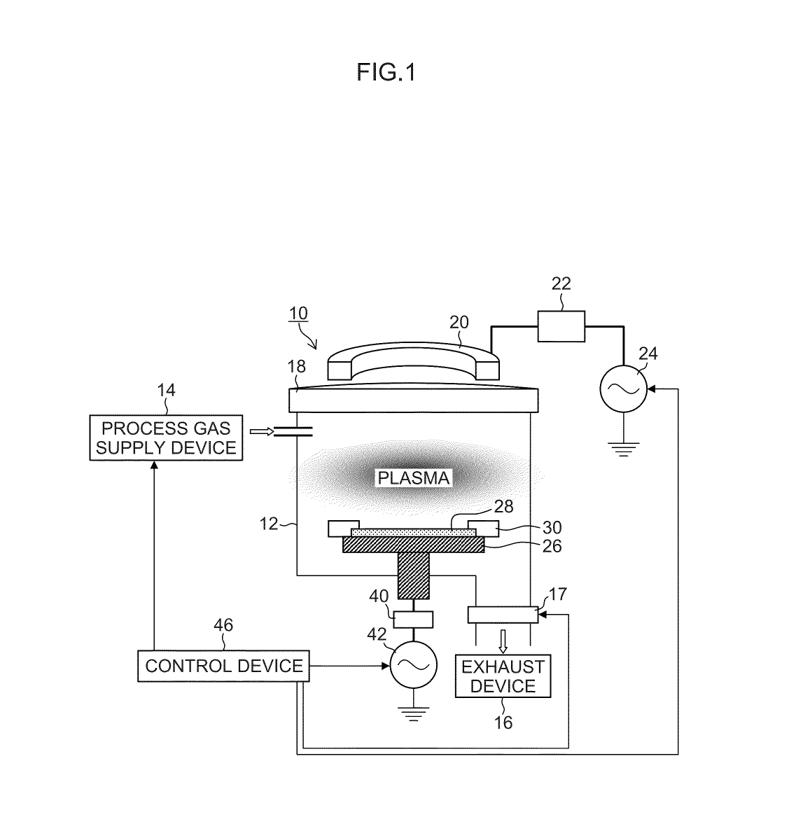

FIG. 1 is a drawing illustrating a schematic configuration of a dry etching apparatus according to an embodiment of the present invention. Here, a description will be made by citing, as an example, an apparatus used for the dry etching of silicon. A dry etching apparatus 10 illustrated in FIG. 1 is of the type in which inductively-coupled plasma (Induction Coupling Plasma: ICP) is applied. The dry etching apparatus is not limited to this type, however. When carrying out the present invention, it is also possible to use a dry etching apparatus in which a method using a source of plasma, such as helicon wave-excited plasma (Helicon Wave Plasma: HWP), electron cyclotron resonance plasma (ECP), or microwave-excited surface-wave plasma (Surface Wave Plasma: SWP) is used is applied.

The dry etching apparatus 10 is provided with a process gas supply device 14 which supplies a process gas (etching gas) into a chamber 12 (vacuum vessel), an exhaust device 16 which discharges gases in the chamber 12, and a pressure adjusting device 17 which adjusts the inner pressure of the chamber 12. The internal pressure of the chamber 12 is adjusted by discharging gases from the exhaust device 16, while supplying the process gas from the process gas supply device 14 into the chamber 12.

A gas containing fluorine atoms is preferably used as the process gas. It is possible to use, for example, sulfur hexafluoride (SF₆), carbon tetrafluoride (CF₄), nitrogen trifluoride (NF₃), methane trifluoride (CHF₃), hexafluoroethane (C₂F6), or octafluorocyclobutane (C₄F₈).

A dielectric window 18 is hermetically fitted on the upper surface of the chamber 12. In addition, a loop coil-shaped antenna 20 is arranged above (on the atmosphere side of) the dielectric window 18. A high-frequency (RF: Radio Frequency) power source 24 for plasma generation is connected to the antenna 20 through a matching circuit (matching unit) 22. A frequency band of 2 to 60 MHz, for example, may be used as the frequency of the high-frequency power source 24 (also referred to as “antenna power supply”). By way of example, it is possible to use 13.56 MHz. In addition, the high-frequency power source 24 may be pulse-driven. The high-frequency power source 24 functions as “power supply for supplying electrical power used to generate plasma within the chamber.”

A stage 26 (sample stage) is arranged within the chamber 12, and a substrate 28 which is a material to be etched is mounted on this stage 26. A substrate cooling mechanism (not illustrated) provided with a clamp 30 for fixing the substrate 28 on the stage 26 is arranged in the stage 26. That is, the clamp 30 fixes the substrate 28 on the stage 26 and is used as a substrate cooling mechanism for cooling the substrate 28 by flowing a helium gas from the rear surface side thereof using an unillustrated helium supply unit. The rise of substrate temperature during etching can be suppressed by flowing high-thermal conductivity helium (He) through the gap between the stage 26 and the substrate 28. In addition to the role of holding down the outer circumference of the substrate 28 to fix the substrate, the clamp 30 has the function of protecting the outer circumference and side surface of the substrate 28 and cooling the substrate 28. The structure of the clamp 30 is described later. Note that it is possible to use the clamp 30 and an electrostatic chuck together.

A biasing power supply (referred to as “bias supply”) 42 is connected to the stage 26 through the matching circuit 40. A frequency of, for example, 200 kHz or higher but not higher than 100 MHz is used as the frequency of the bias supply 42. Preferably, the frequency of the bias supply 42 is 4 MHz or higher but not higher than 27 MHz. By way of example, 13.56 MHz is used.

Like the high-frequency power source 24 for plasma generation, the bias supply 42 may be pulse-driven. In addition, a device which synchronizes the power supply (high-frequency power source 24) of the antenna 20 for plasma generation with the pulse period of the bias supply 42 may be used if the bias supply 42 is used in a pulse-driven mode.

A control device 46 controls the process gas supply device 14, the pressure adjusting device 17, the high-frequency power source 24, and the bias supply 42. Various etching parameters can be adjusted by the control device 46. Specifically, control is performed on the flow rate of a process gas, valves provided in gas supply and exhaust ports, the inner pressure of the chamber 12, the output of the high-frequency power source 24, the output of the bias supply 42, and the like. Note that a control apparatus for controlling the overall range of the dry etching apparatus 10 can also be used as the control device 46.

<Problems with Clamp in Dry Etching Apparatus>

In the case of a structure in which a substrate is fixed (held down) with a clamp, the substrate is held down with a clamp from above a mask material present on the outermost layer of the substrate. Consequently, a mask material on a substrate surface and the rear surface (surface facing the substrate) of the clamp come into direct contact with each other. Although dependent on a material to be etched, a resist material is used for the mask material in many cases (see Japanese Patent Application Laid-Open No. 2002-299422).

As described above, dry etching is performed with the clamp in contact with the resist mask on the substrate. Accordingly, there arises such a problem that substrate temperature rises during dry etching, and therefore, the resist material softens to adhere to the rear surface of the clamp, or particles are generated or a resist comes off. Moreover, the resist material melts, and therefore, the substrate sticks to the clamp.

In particular, the resist mask becomes twice or more thicker on the periphery of the substrate than on the central part thereof if a spin coating method or the like is used when forming the resist mask on the substrate. Thus, such problems as described above are more likely to occur. Since the melting point of resist materials is approximately 100° C. in many cases, the above-described problems are understood to be due to effects of temperature rise during etching.

As described already, in the dry etching apparatus 10 of the present embodiment, efficient temperature control ranging from the stage 26 to the substrate 28 is possible by fixing the substrate 28 with the clamp 30 and flowing helium between the stage 26 and the substrate 28. In addition, the below-described configuration is adopted.

<Clamp Configuration in Present Embodiment>

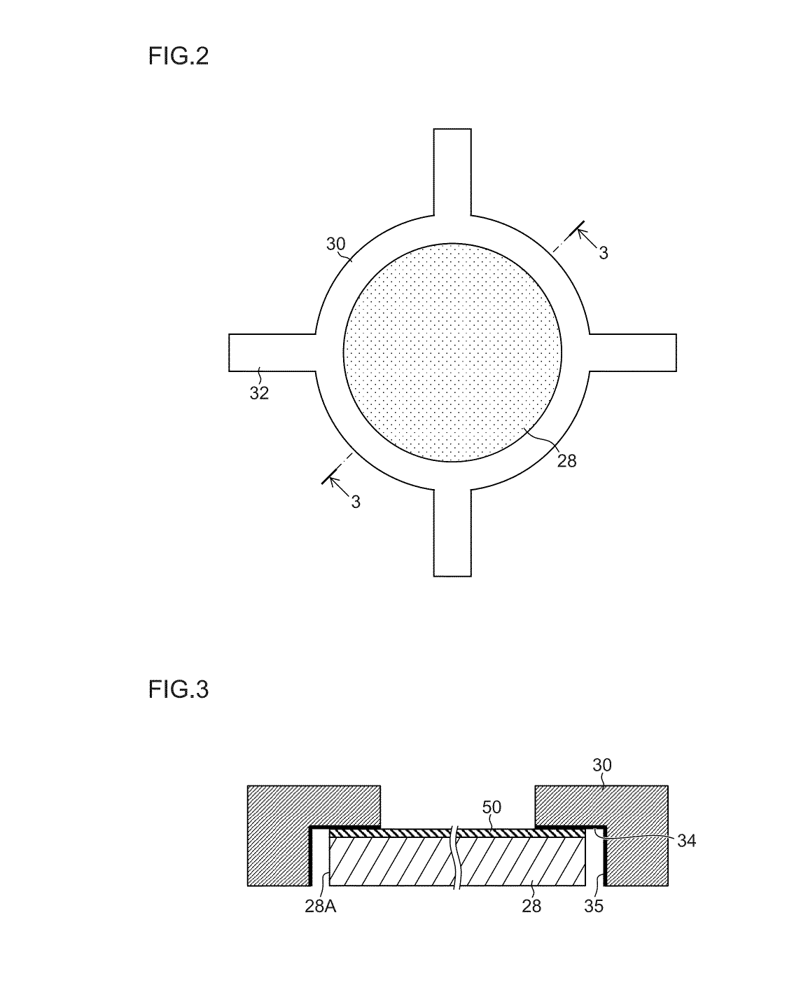

FIG. 2 is a top view of the clamp 30 in the present embodiment, whereas FIG. 3 is a cross-sectional view when the clamp 30 is cut along a cutting plane perpendicular to a substrate surface (when the clamp 30 is cut along the 3-3 line of FIG. 2). As illustrated in FIG. 2, the clamp 30 has an annular (ring) shape capable of covering the entire outer circumference and outer-peripheral side surface of the substrate 28. Note that reference numeral 32 in FIG. 2 denotes a clamp support. The clamp 30 serves to fix the substrate 28 on the stage 26, protect the outer circumference and side surface of the substrate 28, and cool the substrate.

The clamp 30 used in the dry etching apparatus 10 is constantly exposed to plasma containing a corrosive gas or gases. Accordingly, the clamp 30 is desirably composed of a material high in resistance to heat and plasma. It is desirable to use ceramics, such as alumina ceramics, as the material of the clamp 30. In addition, a plasma-resistant coating, such as an yttria coating, may be applied to the front surface (surface in contact with plasma) of the clamp 30.

As illustrated in FIG. 3, a resist mask 50 is formed on the outermost layer of the substrate 28, and the clamp 30 is configured to hold down the substrate 28 from above the resist mask 50. An antiadhesion layer 35 composed of an inorganic film is formed on a portion of the clamp 30 of the present embodiment having contact with the mask material (resist mask 50) on the rear surface side (surface in contact with the substrate 28) of the clamp 30. In addition, an antiadhesion layer 34 composed of an inorganic film is formed on the inner sidewall surface of the clamp 30 covering the side surface (outer-peripheral end face denoted by reference character 28A) of the substrate 28. That is, in the present embodiment, the antiadhesion layers 34 and 35 are respectively formed on the surface of the clamp 30 in contact with the resist mask 50 and on the entire inner sidewall surface of the clamp 30 covering the outer-circumferential side surface of the substrate 28.

The clamp 30 may include the antiadhesion layer 34 at least on the portion of the clamp 30 in contact with the resist mask 50. More preferably, the clamp 30 is configured to include antiadhesion layers on the entire rear surface and inner-circumferential side surface (inner sidewall surface) of the clamp 30, as illustrated in FIG. 3.

The surfaces of the antiadhesion layers 34 and 35 are desirably as planar as possible and 10 μm or smaller in the value of Ra representative of the degree of surface planarity. If the degree of surface planarity of the antiadhesion layers 34 and 35 exceeds 10 μm in the value of Ra, the resist material is likely to adhere to the surfaces. The degree of surface planarity is therefore desirably 10 μm or less in the value of Ra.

[Examples of Material of Inorganic Film Used for Antiadhesion Layers]

(1) For the antiadhesion layers 34 and 35, it is possible to use quartz, alumina (Al₂O₃) or the like which is an insulating material. In addition, as a highly plasma-resistant material, it is possible to use, for example, a material containing sapphire, yttria (Y₂O₃), zirconia (ZrO₂), tantalum pentoxide, or the like. By using an inorganic film containing at least one type of material selected from the group consisting of sapphire, yttria, zirconia, and tantalum pentoxide as the antiadhesion layers 34 and 35, it is possible to further enhance the durability thereof. Consequently, it is possible to extend the period of apparatus maintenance.

(2) In addition, oxygen is prevented from being released during etching treatment by using a material not containing oxygen (for example, metal nitride) as the antiadhesion layers 34 and 35. Consequently, it is possible to enhance the effect of, for example, improving a resist selection ratio. As the antiadhesion layers 34 and 35, it is possible to use, for example, a material containing at least one type of material selected from the group consisting of aluminum nitride (AlN), BN, ZrN, and CrN.

(3) The antiadhesion layers 34 and 35 desirably contain a fluorine group. It is therefore possible to use, for example, a DLC (Diamond Like Carbon) film doped with fluorine (referred to as “fluorine-containing DLC” or “fluorine carbon” in some cases). The fluorine content of the fluorine-containing DLC is desirably 1 to 50%, and particularly preferably 5 to 30%. If the fluorine content is 5% or lower, it is assumed that surface energy is too high (water repellency is low) to fully prevent the adhesion of resist. In addition, if the fluorine content is 30% or higher, the hardness of the film lowers, and therefore, the durability thereof degrades.

(4) In addition to the materials mentioned above, metal containing CaF, MgF or a fluorine group may be used as the material of the antiadhesion layers 34 and 35. It is therefore possible to use, for example, a material containing at least one type of material selected from the group consisting of fluorinated titanium (TiF), aluminum fluoride, and alumina fluoride. Use of a fluorine-containing material lowers surface energy and, thereby, enhances the effect of preventing resist adhesion. In addition, the fluorine-containing material is high in resistance to halogen-based plasma and oxygen plasma and is, therefore, effective as the antiadhesion layers 34 and 35.

(5) Yet additionally, the antiadhesion layers 34 and 35 can be composed of an electroconductive material. By providing the antiadhesion layers 34 and 35 in a path from the surface of the substrate 28 through the clamp 30 to an electrical ground, it is possible to connect the substrate surface to the ground through the antiadhesion layers 34 and 35. Thus, it is possible to prevent the charge-up of the substrate surface.

Accumulation of electrical charges in the resist mask 50 on the substrate surface during etching causes the problem of degradation in an etched shape. In this regard, the charge-up of the substrate 28 is prevented by the use of the electroconductive antiadhesion layer in the present embodiment. Thus, it is possible to obtain an excellent processed shape (verticality) free from shape anomalies, such as bowing, thereby improving the etched shape. As a material high in resistance to plasma and electrically conductive, it is possible to use, for example, a material containing at least one type of material selected from the group consisting of SiC, NiCr, Pt, PtO, Ir, IrO, Ru, and RuO.

<Examples of External Shape of Clamp>

The clamp 30 is formed (circularly), so as to cover the entire outer circumference of the substrate 28. By adopting a clamp structure for seamlessly covering the entire outer circumference of the substrate 28, it is possible to protect the outer circumference and side surface of the substrate 28 during dry etching. Consequently, it is possible to prevent particle generation and ensure the strength of the substrate.

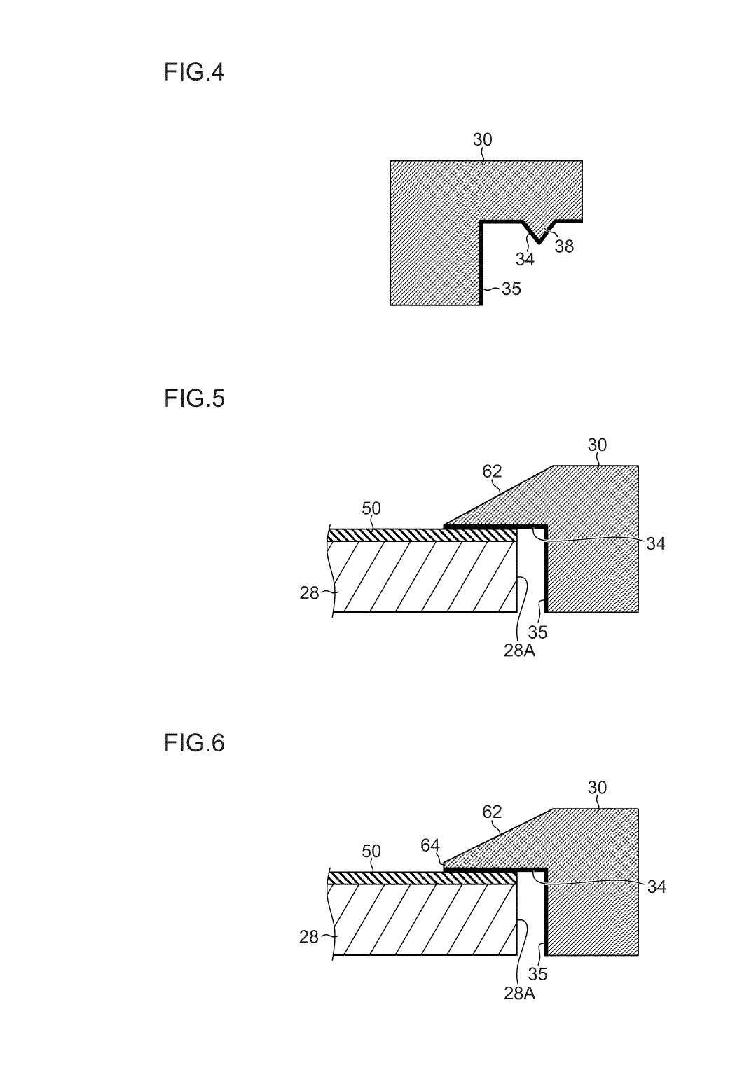

FIG. 4 is a cross-sectional view illustrating a configuration example of a portion of the clamp to have contact with the substrate. Note that like FIG. 3, FIG. 4 is a cross-sectional view when the clamp is cut along a cutting plane perpendicular to the substrate surface.

From the viewpoint of preventing adhesion between the clamp 30 and the resist mask 50, the cross section of the portion of the clamp 30 to have contact with the substrate 28 is desirably V-shaped, as illustrated in FIG. 4. As illustrated in FIG. 4, the area of contact with the substrate 28 is reduced by making a contacting portion 38 of the rear surface of the clamp 30 in contact with the substrate 28 cross-sectionally V-shaped. Consequently, the effect of adhesion prevention is enhanced further.

This cross-sectionally V-shaped contacting portion 38 serves to block the infiltration of plasma into the side surface of the substrate 28. In order to fulfill such a function, the contacting portion 38 is seamlessly and circularly arranged, for example, over the entire backside circumference of the clamp 30.

As another embodiment, a plurality of island-shaped contacting portions 38 may be arranged over the entire backside circumference of the clamp 30. In this embodiment, at least one contacting portion 38 desirably abuts on the substrate 28 along the entire outer circumference thereof, so that plasma does not infiltrate into the side surface of the substrate 28 through gaps in the backside noncontacting portions (portions other than the contacting portions 38) of the clamp 30. Thus, the clamp 30 is desirably configured to hold down the substrate 28 substantially circularly with this plurality of contacting portions 38. In addition, in order to effectively prevent the infiltration of plasma into the side surface of the substrate, the clamp 30 preferably has a labyrinthine structure in which the gaps in the noncontacting portions formed by the layout of the plurality of contacting portions 38 are intricate within a plane, or a closed structure in which the gaps in the noncontacting portions do not reach the side surface of the substrate 28.

FIGS. 5 and 6 illustrate other examples of the cross-sectional shape of the clamp 30. The cross-sectional shape of the clamp 30 on the front surface side (side in contact with plasma) thereof when the clamp 30 is cut along a cutting plane perpendicular to a substrate surface may be quadrangular, as illustrated in FIG. 3. Taking into consideration the uniformity of gas flow, however, the clamp 30 is preferably structured to have a tapered shape 62, as the cross-sectional shape of a cutting plane perpendicular to the substrate surface, in which the thickness of the clamp 30 gradually decreases from the outer peripheral side of the substrate 28 toward the center of the substrate, as illustrated in FIGS. 5 and 6.

In the dry etching apparatus 10 described in FIG. 1, a process gas is supplied from the upper portion of the chamber 12, thus causing a flow of gas in the direction downward from above the substrate 28 toward the substrate 28 (from top to bottom in FIG. 1). The gas flow having reached the front surface of the substrate 28 hits against the substrate surface and turns around. Thus, the gas flows toward the outer-circumferential end (side surface) of the substrate 28. At this time, the gas flow is affected by the external shape of the clamp 30.

If the cross-sectional shape of the clamp 30 is quadrangular like the shape illustrated in FIG. 3, the leading end of the clamp 30 serves as a wall standing upright with respect to a gas flowing along the substrate surface toward the outer side of the substrate 28. Accordingly, it is difficult for the gas to flow toward the outer side, and therefore, the gas flow is likely to become turbulent.

In contrast, in the example illustrated in FIG. 5, the cross-sectional shape of the clamp 30 on the front surface side thereof is a tapered shape 62. From the viewpoint of gas flow, such a tapered shape 62 forms an inclined surface in which the thickness of the clamp 30 gradually increases toward the outer side of the substrate 28. Accordingly, a stream of gas flowing along the substrate surface toward the outer side of the substrate 28 is stabilized along the inclined surface of the tapered shape 62 of the clamp 30. In this way, the gas is made easy to escape toward the outer side of the substrate 28 by the tapered shape 62 of the clamp 30. Thus, it is possible to obtain a uniform gas flow. Consequently, etching uniformity can be improved.

Note that if the cross-sectional shape of the clamp 30 on the front surface side thereof is only formed into the tapered shape 62 as in FIG. 5, the leading end of the clamp 30 decreases in strength. Accordingly, as illustrated in FIG. 6, the leading end of the clamp is formed into a vertical surface 64 capable of securing a required thickness (strength). More preferably, the clamp 30 is configured so that the front surface side thereof (side exposed to plasma) has a tapered shape 62 in combination with such a vertical surface 64.

According to the configuration illustrated in FIG. 6, it is possible to satisfy requirements for both the strength of the leading end of the clamp 30 and etching uniformity based on a uniform gas flow.

<Another Embodiment>

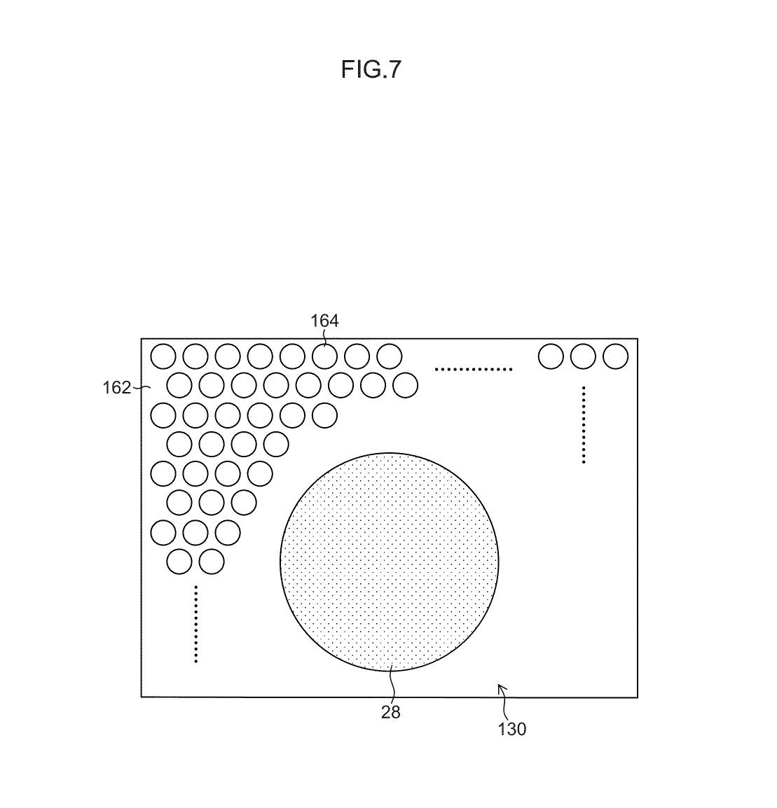

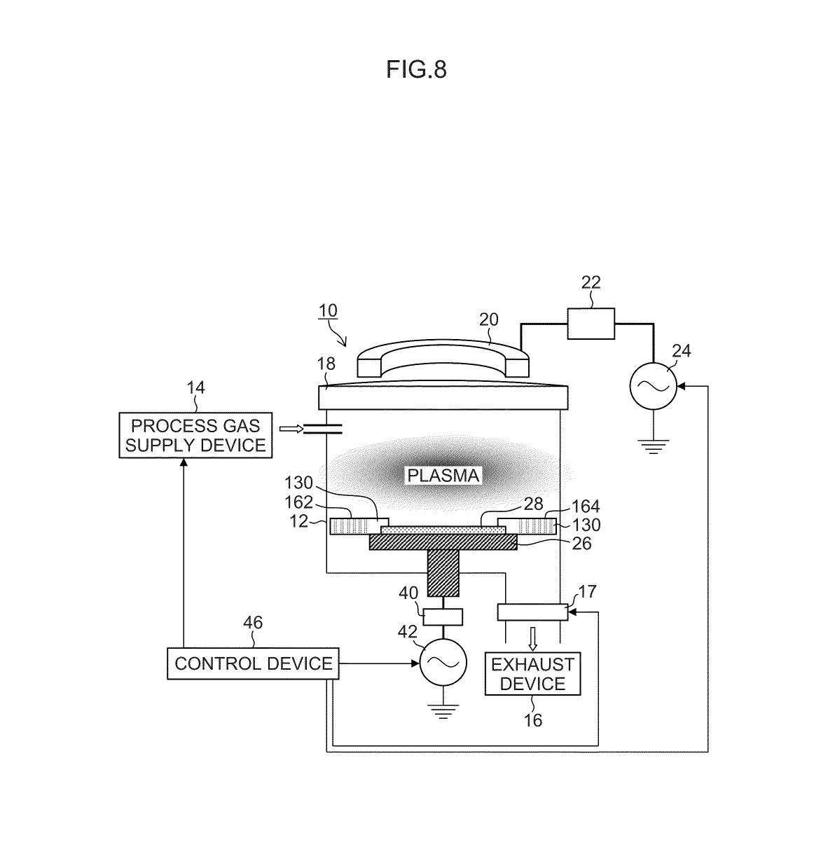

FIG. 7 illustrates an example of a clamp integrated with a straightening vane capable of further improving the uniformity of gas flow. FIG. 7 is a top view, whereas FIG. 8 is a configurational view of a dry etching apparatus to which the clamp of FIG. 7 is applied. In FIG. 8, constituent elements identical or similar to those described in FIG. 1 are denoted by like reference numerals and will not be discussed again here.

While FIG. 7 illustrates a clamp 130 rectangular in plan view and integrated with a straightening vane, the planar shape of the clamp 130 is designed in conformity with the shape of the chamber 12.

As illustrated in FIGS. 7 and 8, the clamp 130 is structured to cover the entire space between a stage 26 and the chamber 12 in plan view, and has the functions as the clamp 30 described in FIGS. 2 to 6 and as a straightening vane for straightening a gas flow inside the chamber 12. The term “entire” as used here is not limited to “entirety” in a strict sense. Instead, the term includes meanings that can be understood as substantially and basically “entire,” though not “entirety” in a strict sense, to the extent of being able to achieve the objective that the straightening vane works so as to be able to substantially ensure the uniformity of gas flow at the time of substrate etching. That is, the term “entire,” when interpreted, includes the meaning of “substantially entire (basically entire).”

In the clamp 130 illustrated in FIGS. 7 and 8, a straightening vane 162 is arranged in the space between the stage 26 and the walls of the chamber 12. A plurality of holes (through-holes) 164 for a gas to pass through are formed in the straightening vane 162. Although simply illustrated in FIG. 7, the plurality of holes 164 are formed in an appropriate layout pattern (for example, a symmetrically-structured configuration having isotropy on the average around the substrate 28), so that a gas uniformly flows with respect to the substrate 28.

A commonly-used dry etching apparatus has such a problem that since a gas tends to flow toward the exhaust side (side where a pump is located) of a chamber, the etching rate is faster on the exhaust side.

In this regard, a gas flow within the whole interior of the chamber 12 can be improved by adopting such a clamp structure (clamp 130) integrated with a straightening vane as illustrated by way of example in FIGS. 7 and 8. Consequently, a gas flow over the stage 26 is made uniform, thereby improving the in-plane uniformity of etching.

<Application Examples>

Although designed for use with a dry etching apparatus, the clamp is highly effective when used in a deep etching apparatus for silicon in particular. Since a thick-film resist mask is used when performing deep silicon etching using a resist mask, the resist mask is ready to adhere to the clamp.

In addition, in the case of the deep etching of silicon, the outer circumference and side surface of a substrate is abraded due to etching in a conventional apparatus. On the other hand, the outer circumference and side surface of the substrate can be prevented from being abraded by the use of the clamp which is described in the present embodiment and covers the entire outer circumference of the substrate. Note that the deep etching of silicon is frequently used in the manufacture of, for example, MEMS devices. For example, the deep etching of silicon is used to form the ink flow path of an ink-jet head.

For the mask material, it is possible to use photosensitive resin, such as photoresist. As the photoresist, it is possible to use, for example, the OFPR Series or the TSMR Series made by Tokyo Ohka Kogyo Co., Ltd., or the 1500 Series or the 6000 Series made by AZ Electronic Materials.

Dry etching in the present embodiment is preferably based on a Bosch process in which etching and protective film-forming deposition are performed repeatedly, or on a method in which a fluorine-based gas is admixed with oxygen. It is more preferable, however, to use a Bosch process that allows the use of a resist mask.

The Bosch process is a method of repeatedly performing etching and protective film formation using SF₆ (sulfur hexafluoride) or a mixed gas of SF₆ and O₂ (oxygen) at the time of etching and C₄F₈ (octafluorocyclobutane) (while forming a sidewall protective film) at the time of forming a protective film.

<Advantages of Embodiments>

According to the above-described embodiments of the present invention, the following advantages are provided:

[1] A resist material can be prevented from adhering to the rear surface of a clamp.

[2] The outer circumference and side surface of a substrate can be prevented from being abraded due to etching.

[3] Particle generation can be suppressed.

[4] The period of apparatus maintenance is extended, compared with a conventional configuration, thus improving an operating rate.

<Other Application Examples>

While in the foregoing description, the dry etching of silicon is cited as an example, the material to be etched is not limited to silicon. The present invention can be widely applied to dry etching apparatuses in which patterning is performed using a resist mask.

It should be noted that the present invention is not limited to the above-described embodiments, but various modifications may be made thereto by those of ordinary skill in the art within the technical scope of the present invention.

What is claimed is:

1. A dry etching apparatus comprising:
a stage on which a substrate including a resist mask on an outermost layer thereof is mounted;
a clamp for holding down the substrate from above the resist mask to fix the substrate on the stage;
a chamber within which the stage and the clamp are housed;
an exhaust device which evacuates the chamber;
a process gas supply device which supplies a process gas into the chamber; and
a power supply for supplying electrical power used to generate plasma within the chamber, wherein
the clamp has an annular structure for covering an entire outer circumference and side surface of the substrate, and
an antiadhesion layer composed of an inorganic film for preventing an adhesion of a resist material is formed on a contact surface side of the clamp in contact with the substrate.

2. The dry etching apparatus according to claim 1, wherein the degree of planarity of a surface of the antiadhesion layer is 10 μm or lower in terms of a value of Ra.

3. The dry etching apparatus according to claim 1, wherein the antiadhesion layer is composed of an inorganic film containing at least one type of material selected from a group consisting of quartz, alumina, sapphire, yttria, zirconia, and tantalum pentoxide.

4. The dry etching apparatus according to claim 1, wherein the antiadhesion layer is composed of metal nitride.

5. The dry etching apparatus according to claim 1, wherein the antiadhesion layer is composed of an inorganic film containing a fluorine group.

6. The dry etching apparatus according to claim 1, wherein the antiadhesion layer is composed of an electroconductive material.

7. The dry etching apparatus according to claim 6, wherein the antiadhesion layer is composed of an electroconductive material containing at least one type of material selected from a group consisting of SiC, NiCr, Pt, PtO, Ir, IrO, Ru, and RuO.

8. The dry etching apparatus according to claim 1, wherein the antiadhesion layer composed of an inorganic film is also provided on an inner sidewall surface of the clamp surrounding a side surface of the substrate.

9. The dry etching apparatus according to claim 1, wherein a portion of the clamp in contact with the substrate has a V-shape as the cross-sectional shape of a cutting plane perpendicular to a substrate surface.

10. The dry etching apparatus according to claim 1, wherein the clamp has a structure including a tapered shape, as a cross-sectional shape of a cutting plane perpendicular to a substrate surface, in which a thickness of the clamp decreases from an outer periphery of the substrate toward a center thereof

11. The dry etching apparatus according to claim 1, wherein the clamp has a structure of being integrated with a straightening vane for covering a space between the stage and walls of the chamber, and a plurality of holes for a gas to flow through are provided in the straightening vane.

12. A clamp for a dry etching apparatus used to hold down a substrate including a resist mask on an outermost layer thereof from above the resist mask and fix the substrate on a stage of the dry etching apparatus, the clamp having an annular structure for covering an entire outer circumference and a side surface of the substrate, wherein
an antiadhesion layer composed of an inorganic film for preventing an adhesion of the resist mask is formed on a surface of the clamp in contact with the substrate.
